(19) United States
(12) Patent Application Publication
(10) Pub. No.: US 2023/0153158 A1
(43) Pub. Date: May 18, 2023

(54) METHOD, APPARATUS, SYSTEM, AND STORAGE MEDIUM FOR PERFORMING EDA TASK

(71) Applicant: XEPIC CORPORATION LIMITED, Nanjing (CN)

(72) Inventors: Ye YANG, Shanghai (CN); Lifeng XU, Shanghai (CN)

(21) Appl. No.: 17/955,178

(22) Filed: Sep. 28, 2022

(30) Foreign Application Priority Data
Nov. 17, 2021 (CN) 202111374748.4

(51) Int. Cl. G06F 9/50; G06F 30/30

(52) U.S. Cl. CPC G06F 9/5038; G06F 9/5066; G06F 30/30; G06F 2209/5017

(57) ABSTRACT

Embodiments of the disclosure provide a method, apparatus, system, and storage medium for performing an EDA task. The method comprises: reconstructing the EDA task into a plurality of subtasks that are executed according to a given process, the plurality of subtasks comprising a first subtask and a second subtask; determining a plurality of computing resources corresponding to the plurality of subtasks, the plurality of computing resources comprising a first computing resource corresponding to the first subtask and a second computing resource corresponding to the second subtask; and invoking the plurality of computing resources according to the given process to execute the plurality of subtasks.

### CROSS-REFERENCE TO RELATED APPLICATION

This application claims the benefits of priority to Chinese Application No. 202111374748.4, filed Nov. 17, 2021, the entire content of which is incorporated herein by reference.

### TECHNICAL FIELD

The present disclosure relates to the technical field of computers, and in particular, to a method, apparatus, system, and storage medium for performing an Electronic Design Automation (EDA) task.

### BACKGROUND

In recent years, as the scale of an integrated chip (IC) design increases, the local computing power can be insufficient during the verification process of the IC design. Furthermore, the verification process usually involves a plurality of tools, such as a simulator, a formal verification tool, an emulator (including a prototyping apparatus). A full process of an IC design involves even more tools.

Therefore, in the IC design industry, some tools can be short of computing resources during a specific period, while some other tools cannot make full use of computing resources because the tool chain is too long.

How to integrate existing EDA tools and improve the efficiency of computing resources is an urgent problem to be addressed.

### SUMMARY

Therefore, there is provided a method, apparatus, system, and storage medium for performing an EDA task.

Embodiments of the disclosure provide a method for performing an EDA task, the method comprising: reconstructing the EDA task into a plurality of subtasks that are executed according to a given process, the plurality of subtasks comprising a first subtask and a second subtask; determining a plurality of computing resources corresponding to the plurality of subtasks, the plurality of computing resources comprising a first computing resource corresponding to the first subtask and a second computing resource corresponding to the second subtask; and invoking the plurality of computing resources according to the given process to execute the plurality of subtasks.

Embodiments of the disclosure also provide a computing apparatus for performing an EDA task, comprising: a memory storing a set of instructions; and at least one processor configured to execute the set of instructions to perform a method for performing the EDA task, the method comprising: reconstructing the EDA task into a plurality of subtasks that are executed according to a given process, the plurality of subtasks comprising a first subtask and a second subtask; determining a plurality of computing resources corresponding to the plurality of subtasks, the plurality of computing resources comprising a first computing resource corresponding to the first subtask and a second computing resource corresponding to the second subtask; and invoking the plurality of computing resources according to the given process to execute the plurality of subtasks.

Embodiments of the present disclosure provide a computing system for performing an EDA task, comprising: the computing apparatus for performing an EDA task as described above; and local computing resources communicatively connected to the computing apparatus. The local computing resources comprise: at least one of a server or a hardware verification tool.

Embodiments of the present disclosure provide a non-transitory computer-readable storage medium that stores a set of instructions of a computing apparatus. The set of instructions is used to cause the computing apparatus to perform a method for performing an EDA task, the method comprising: reconstructing the EDA task into a plurality of subtasks that are executed according to a given process, the plurality of subtasks comprising a first subtask and a second subtask; determining a plurality of computing resources corresponding to the plurality of subtasks, the plurality of computing resources comprising a first computing resource corresponding to the first subtask and a second computing resource corresponding to the second subtask; and invoking the plurality of computing resources according to the given process to execute the plurality of subtasks.

### BRIEF DESCRIPTION OF THE DRAWINGS

To describe the technical solutions in the present disclosure more clearly, the following will briefly introduce the figures that need to be used in the embodiments. Obviously, the figures in the following description are merely exemplary, for those ordinary skilled in the art, without inventive work, other figures can be obtained based on these figures.

FIG. 1A illustrates a schematic diagram of a computing apparatus according to embodiments of the present disclosure.

FIG. 1B illustrates a schematic diagram of a cloud system according to embodiments of the present disclosure.

FIG. 1C illustrates a schematic diagram of an EDA computing system according to embodiments of the present disclosure.

FIG. 2A illustrates a schematic diagram of an architecture of a resource manager according to embodiments of the present disclosure.

FIG. 2B is a flowchart of a reconstructed process according to embodiments of the present disclosure.

FIG. 2C is a flowchart of another reconstructed process according to embodiments of the present disclosure.

FIG. 3 is a flowchart of a method for performing an EDA task according to embodiments of the present disclosure.

### DETAILED DESCRIPTION

Exemplary embodiments will be described in detail herein, and examples thereof are shown in the accompanying drawings. In the following description involving the accompanying drawings, the same numerals in different accompanying drawings indicate the same or similar elements, unless specified otherwise. Implementations described in the following exemplary embodiments do not represent all implementations consistent with the disclosure. In contrast, they are merely examples of devices and methods consistent with some aspects of the disclosure as described in detail below.

Terms in the disclosure are merely used for describing specific embodiments, rather than limiting the disclosure. Singular-form words “a (an)”, “said”, and “the” used in the present disclosure and the appended claims also include plural forms, unless clearly specified in the context that other meanings are denoted. It should be further understood that the term “and/or” used herein refers to and includes any or all possible combinations of one or more associated items listed.

It should be understood that, although terms such as “first”, “second”, and “third” can be used to describe various kinds of information in the disclosure, these kinds of information should not be limited by the terms. These terms are merely used to distinguish information of the same type from each other. For example, without departing from the scope of the disclosure, the first information can also be referred to as second information, and similarly, the second information can also be referred to as first information. Depending on the context, the word “if” used herein can be understood as “when . . . ”, “as . . . ”, or “in response to the determination”.

While ordinary software technology or software engineering can be capable of completing software design tasks with the assistance of very few tools, EDA technology for designing an IC can involve dozens of EDA tools, and the EDA tools need to be separately used according to the progress of EDA tasks. Conventionally, an engineer can use an EDA tool to complete an EDA task and then manually provide the results generated by the EDA tool to another EDA tool for the execution of a next EDA task.

These inherent characteristics of EDA tools at least lead to the following problems.

Firstly, it is inefficient to manually invoke a plurality of EDA tools. Obviously, manually invoking EDA tools requires engineers to keep an eye on the running status of EDA tasks, and to manually provide the task results of the previous tool to the next tool. These operations are inefficient.

Secondly, because the resource configuration cannot be globally performed, a shortage of some computing resources (e.g., emulators) can cause a plurality of EDA tasks to wait. Generally, IC design companies can only afford a small number of emulators because the emulators (e.g., HuaEmu of XEPIC Corporation Limited) are expensive. While a plurality of verification work groups within an IC design company need to use emulators, there can be a wait due to the shortage of emulators. It is essentially due to the lack of global resource configuration.

Thirdly, the task results cannot be reused and corroborated with each other across a plurality of EDA tools. For example, conventionally, a waveform file generated by a simulator during verification and a waveform file generated by an emulator during verification cannot be reused and corroborated with each other. The above problem is caused by the isolation of a plurality of EDA tools from each other.

Fourthly, because conventional cloud computing requires users to provide source codes of IC designs, users are less motivated to use the cloud computing for computing flexibility.

Embodiments of the disclosure provide a method, apparatus, system, and computer-readable storage medium for performing an EDA task to construct a new EDA architecture, intended to at least partially resolve the above-mentioned problems.

The disclosure only takes a verification tool and a verification task of a logic system design as examples for illustration. But it should be understood that, the method, apparatus, system, and computer-readable storage medium for performing an EDA task provided by embodiments of the disclosure can be applied to various EDA tools, instead of being limited to verification tools.

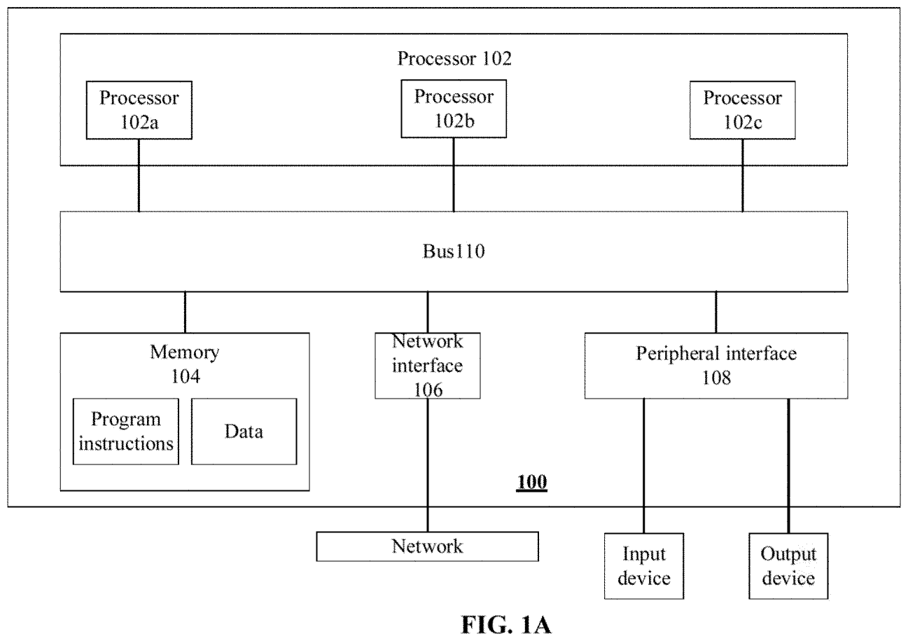

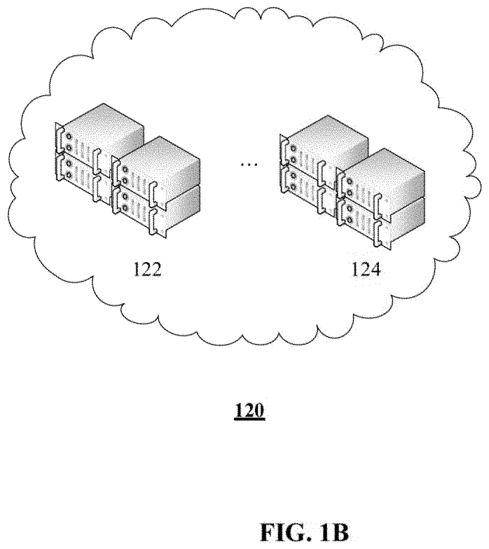

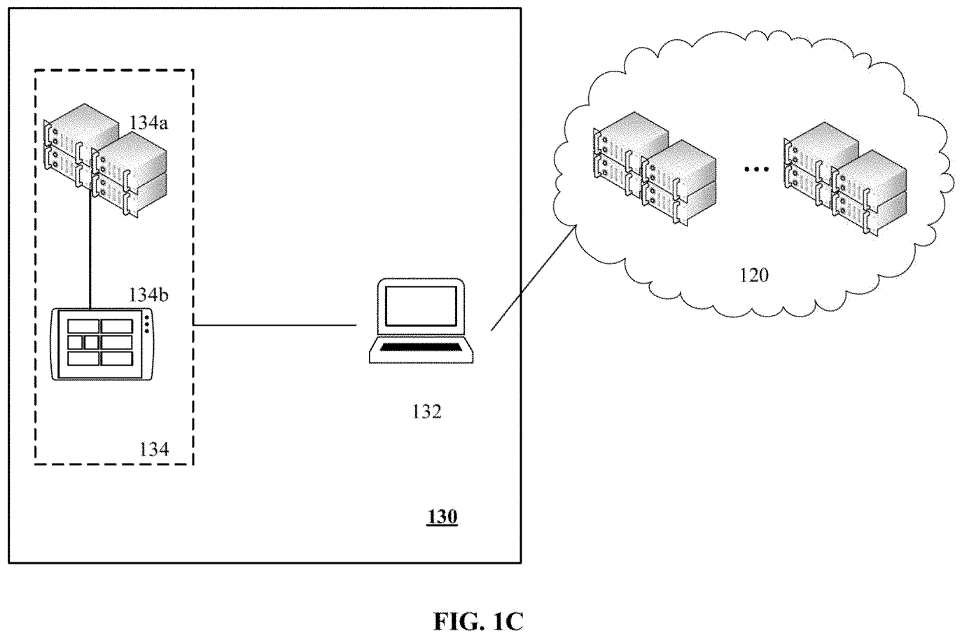

FIG. 1A illustrates a schematic diagram of a computing apparatus 100 according to embodiments of the present disclosure. As shown in FIG. 1A, the computing apparatus 100 can include: a processor 102, a memory 104, a network interface 106, a peripheral interface 108, and a bus 110. Processor 102, memory 104, network interface 106, and peripheral interface 108 can communicate with each other through bus 110 in the computing apparatus.

Processor 102 can be a central processing unit (CPU), an image processor, a neural network processor (NPU), a microcontroller (MCU), a programmable logical device, a digital signal processor (DSP), an application specific integrated circuit (ASIC), or one or more integrated circuits. Processor 102 can perform functions related to the techniques described in the disclosure. In some embodiments, processor 102 can also include a plurality of processors integrated into a single logical component. As shown in FIG. 1A, processor 102 can include a plurality of processors 102a, 102b, and 102c.

Memory 104 can be configured to store data (e.g., an instruction set, lists of TCL objects, computer codes, properties of objects and values of properties, etc.). As shown in FIG. 1A, the stored data can include program instructions (e.g., program instructions used to implement the method for displaying the target module of the logical system design of the present disclosure) and the data to be processed (e.g., memory 104 can store temporary codes generated during compiling, properties of objects and values of properties, etc.). Processor 102 can also access stored program instructions and data, and execute the program instructions to operate the data to be processed. Memory 104 can include a volatile storage device or a non-volatile storage device. In some embodiments, memory 104 can include a random-access memory (RAM), a read-only memory (ROM), an optical disk, a magnetic disk, a hard disk, a solid-state disk (SSD), a flash memory, a memory stick, and the like.

Network interface 106 can be configured to enable computing apparatus 100 to communicate with other external devices via a network. The network can be any wired or wireless network capable of transmitting and receiving data. For example, the network can be a wired network, a local wireless network (e.g., a Bluetooth network, a Wi-Fi network, a near field communication (NFC), etc.), a cellular network, the Internet, or a combination of the above. It is appreciated that the type of network is not limited to the above specific examples. In some embodiments, network interface 106 can include any number of network interface controllers (NICs), radio frequency modules, receivers, modems, routers, gateways, adapters, cellular network chips, or random combinations of two or more of the above.

Peripheral interface 108 can be configured to connect the computing apparatus 100 to one or more peripheral devices to implement input and output information. For example, the peripheral devices can include input devices, such as keyboards, mice, touch pads, touch screens, microphones, various sensors, and output devices, such as displays, speakers, vibrators, and indicator lights.

Bus 110, such as an internal bus (e.g., a processor-storage bus), an external bus (e.g., a USB port, a PCI-E bus), and the like, can be configured to transmit information among various components of computing apparatus 100 (e.g., processor 102, memory 104, network interface 106, and peripheral interface 108).

It should be noted that, although the above computing apparatus merely illustrates processor 102, memory 104, network interface 106, peripheral interface 108, and bus 110, the computing apparatus architecture can also include other components needed for normal operations. In addition, it can be appreciated for those ordinary skilled in the art that the foregoing devices can also include the components needed to implement the solutions of embodiments of the present disclosure and do not require to include all the components of figures.

FIG. 1B illustrates a schematic diagram of a cloud system 120 according to embodiments of the present disclosure.

As shown in FIG. 1B, cloud system 120 can include a plurality of cloud servers (122, 124). These cloud servers can be, for example, computing apparatus 100 as shown in FIG. 1A or computers provided by a cloud computing server. Cloud system 120 can be used to provide cloud computing resources. Therefore, cloud system 120 is also referred to herein as cloud computing resource 120.

FIG. 1C illustrates a schematic diagram of an EDA computing system 130 according to embodiments of the present disclosure.

EDA computing system 130 of the present disclosure can be a local computing system, and can include a computing device 132 and a local computing resource 134.

Computing device 132 can be computing apparatus 100 as shown in FIG. 1A. Computing device 132 can provide a resource manager to users and provide an interface to connect cloud system 120 and an interface to connect computing resources 134a and 134b. Local host 132 can also allocate different computing tasks to the cloud or the local computing resources accordingly. Further descriptions will be provided below.

Local computing resource 134 can provide users with a plurality of EDA tools and vessels for running the EDA tools. In some embodiments, local computing resource 134 can include at least one of server 134a or hardware verification tool 134b.

Server 134a can be computing apparatus 100 as shown in FIG. 1A. In some embodiments, server 134a can run at least one of EDA software tools (e.g., a simulator, a formal verification tool, etc.). Server 134a can also serve as a host of hardware verification tool 134b, and it is used to cooperate with hardware verification tool 134b to complete the verification tasks and read the verification results.

Hardware verification tool 134b can exemplarily include hardware verification tools, such as a prototype verification board or an emulator.

Although only a limited number of local computing resource 134 are shown in FIG. 1C, those ordinary skilled in the art can understand that any number of local computing resources 134 can be provided according to practical needs. That is, there can be a plurality of servers 134a and a plurality of hardware verification tools 134b. Server 134a and hardware verification tool 134b are also not necessarily provided in a one-to-one pairing. For example, one server 134a can interface with a plurality of hardware verification tools.

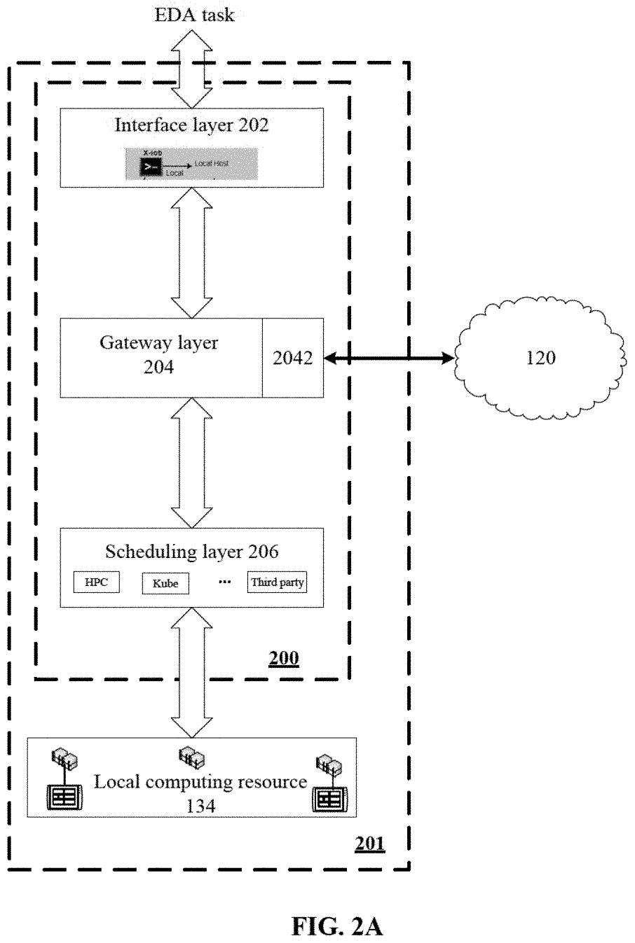

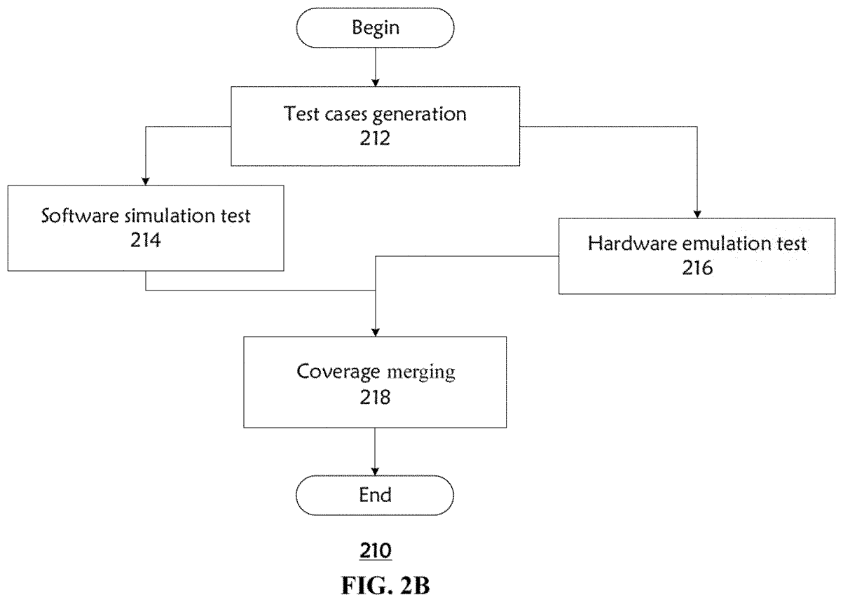

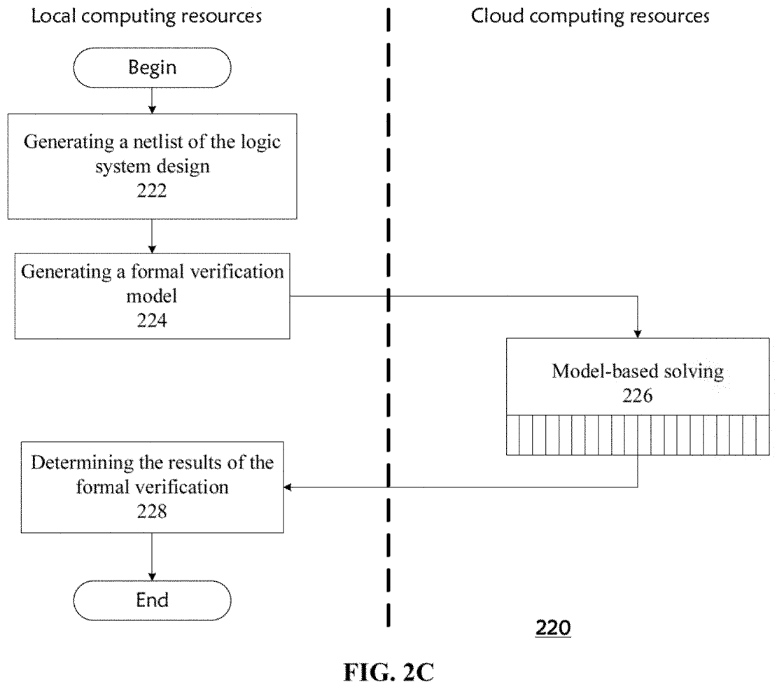

FIG. 2A illustrates a schematic diagram of an architecture of a resource manager 200 according to embodiments of the present disclosure. Resource manager 200 can be executed by computing device 132 as shown in FIG. 1C. It is appreciated that although only one computing device 132 is shown in FIG. 1C as an example, computing device 132 can include a plurality of computing devices.

As shown in FIG. 2A, resource manager 200 can include an interface layer 202, a gateway layer 204, and a scheduling layer 206. Resource manager 200 can be further connected to local computing resources 134. Resource manager 200 and local computing resources 134 can form a computing system 201. It is appreciated that computing system 201 can be a local system, that is, the system is directly controlled by the user.

Interface layer 202 can be configured to provide an interactive interface to a user. In some embodiments, interface layer 202 can provide a command line console or a graphic interface to a user (e.g., an employee of an IC design company). The command line console or the graphic interface allows the user to initiate EDA tasks (e.g., a simulation task, a formal verification task, etc.), trace the execution of EDA tasks, and read the execution results of EDA tasks (e.g., waveform files, coverage files, etc.).

In some embodiments, interface layer 202 can provide a graphic interface to a user for configuring computing resources for each EDA task. Usually, an IC design company can carry out a plurality of IC design projects in parallel, and there are a plurality of sub-projects within one design project that need to perform EDA tasks. These projects or sub-projects can compete for the limited resources controlled by resource manager 200 to perform the required EDA tasks at the same time. Interface layer 202 can allow the user to assign resources for different projects or EDA tasks. For example, different projects can be assigned with different levels, each level corresponding to different permissions to allocate resources and the maximum number of resources allowed to be used.

Interface layer 202 can send these EDA task instructions (e.g., instructions to initiate an EDA task, configure computing resources) from the user to gateway layer 204, so as to allocate the computing resources to perform the EDA task.

According to the EDA task, gateway layer 204 can be configured to reconstruct the EDA task from interface layer 202 into a process and a plurality of subtasks that are executed according to the process. The reconstructed process can include the execution order of the plurality of subtasks, thereby allowing the plurality of subtasks to be executed according to the reconstructed process.

Gateway layer 204 can also be configured to be connected to cloud system 120, so that one or more subtasks can be sent to cloud system 120 for computing, thereby realizing the invocation of cloud computing resources. In some embodiments, gateway layer 204 can include a security gateway 2042 to ensure that communications between gateway layer 204 belonging to the local computing system and external cloud system 120 are secure. It is appreciated that gateway layer 204 can be connected with cloud systems provided by a plurality of cloud service providers.

In some embodiments, interface layer 202 and gateway layer 204 can be provided by separate computing devices 132. For example, interface layer 202 can be implemented on a specific user's personal computer, while gateway layer 204 can be implemented on a server connected to the personal computer. In some embodiments, interface layer 202 and gateway layer 204 can be implemented by the same computing device 132.

Gateway layer 204 can select EDA tools corresponding to these subtasks and allocate corresponding computing resources for the selected EDA tools. It is appreciated that gateway layer 204 can merely select one or more EDA tools among the EDA tools provided by computing resources 134. In some embodiments, gateway layer 204 can provide the user with suggestions for adding a new EDA tool that is required by the EDA task but not provided by computing resources 134 via interface layer 202.

In some embodiments, the EDA task from interface layer 202 can be a coverage testing task of an IC design. In response to receiving the EDA task, gateway layer 204 can reconstruct the task and generate a reconstructed process. FIG. 2B is a flowchart of a reconstructed process 210 according to embodiments of the present disclosure.

As shown in FIG. 2B, the EDA task for coverage testing can be decomposed into a reconstructed process 210 having a plurality of subtasks. The plurality of subtasks can include test cases generation 212, a software simulation test 214, a hardware emulation test 216, coverage merging 218, and the like. Gateway layer 204 can select, for example, GalaxPSS tool provided by XEPIC Corporation Limited for test cases generation 212, GalaxSim tool provided by XEPIC Corporation Limited for software simulation test 214, HuaEmu tool provided by XEPIC Corporation Limited for hardware emulation test 216, and invoking XDB database tool provided by XEPIC Corporation Limited for coverage merging 218.

Reconstructed process 210 can also specify the execution order of each subtask. As shown in FIG. 2B, after test cases generation 212 is completed, software simulation test 214 and hardware emulation test 216 can be started in parallel. In some embodiments, gateway layer 204 can generate an execution result of the EDA task according to the sub-execution results of the plurality of subtasks. In this example, the sub-execution results of software simulation test 214 and hardware emulation test 216 need to be aggregated into coverage merging 218 to obtain the final coverage test result. It is appreciated that, generating the final execution result of the EDA task can also be performed by one of the servers in computing resource 134. In this way, the collaboration between a plurality of EDA tools can be guaranteed, and the results of the software simulation test and the hardware emulation test can be stored in the same database, which is convenient for subsequent reuse and corroboration with each other.

In some embodiments, when a subtask is completed, the corresponding resource can be released for use by other tasks. For example, after hardware emulation test 216 is completed, the corresponding hardware verification tool can return the execution result to gateway layer 204 and the hardware verification tool can be released.

In some embodiments, an EDA task from interface layer 202 can be a formal verification task of an IC design. In response to receiving the EDA task, gateway layer 204 can similarly reconstruct the task and generate a reconstructed process. FIG. 2C is a flowchart of another reconstructed process 220 according to embodiments of the present disclosure.

As shown in FIG. 2C, the EDA task for formal verification can be decomposed into a reconstructed process 220 having a plurality of subtasks. The plurality of subtasks can include generating (222) a netlist of the logic system design, generating (224) a formal verification model, model-based solving (226), and determining (228) the results of the formal verification according to the results of a plurality of solvers, and the like. Gateway layer 204 can select, for example, GalaxSim tool provided by XEPIC Corporation Limited for generating the netlist of the logic system design, GalaxFV tool provided by XEPIC Corporation Limited for generating the formal verification model and determining the results of the formal verification according to the results of a plurality of solvers, and the plurality of solvers of GalaxFV tool provided by XEPIC Corporation Limited for model-based solving.

Reconstructed process 220 can also specify the execution order of each subtask. As shown in FIG. 2C, after the sequential execution of generating (222) the netlist of the logic system design and generating (224) the formal verification model, model-based solving (226) and determining (228) the results of the formal verification according to the results of the plurality of solvers can be performed.

Gateway layer 204 can allocate computing resources for each subtask according to the characteristics of the subtask.

In some embodiments, gateway layer 204 can determine whether each of the above-described plurality of subtasks is suitable for cloud computing. In the conventional cloud computing, when a computing task requires computing elasticity (that is, it can require a large amount of computing resources in a short period of time), it can be considered that the computing task is suitable for cloud computing. However, in the EDA industry, users pay more attention to the source code security of the IC design, in addition to the consideration of computing elasticity requirements. Thus, in one example, gateway layer 204 can determine whether an input of each subtask is source code secure. The source code here refers to the source code of the logic system design related to the EDA task. If it is determined that the input of a subtask is not source code secure, a local computing resource can be allocated for the subtask as the computing resource. In this way, it can be ensured that the execution of the subtask is performed in a local secured environment without any risk of leaking the source code. If it is determined that the input of a subtask is source code secure, a cloud computing resource (e.g., cloud system 120) can be allocated for the subtask as the computing resource. In this way, the advantages of cloud computing can be fully utilized to accelerate EDA tasks.

As shown in FIG. 2C, in the above formal verification task, the subtasks of generating (222) the netlist of the logic system design, generating (224) the formal verification model, and determining (228) the results of the formal verification are not source code secure (the source code of the logical system design needs to be read first), while the model-based solving (226) is source code secure (the modeled model is isolated from the source code). In addition, in the process of the formal verification, a plurality of models can be generated according to the logic system design, and each model can be solved by using a plurality of solvers. This allows the “model-based solving” subtask to be further decomposed into a plurality of grandchild tasks, and these grandchild tasks are highly parallel. Because the “model-based solving” subtask has both the characteristics of source code security and high parallelism, gateway layer 204 can determine that the subtask is suitable for cloud computing, and allocate cloud computing resources for the subtask.

As another example, as shown in FIG. 2B, in the above coverage testing task, subtasks such as test cases generation 212, software simulation test 214, hardware emulation test 216 need to be performed based on the source code of the logic system design, thus gateway layer 204 can determine that the inputs of these subtasks are not source code secure, and allocate local computing resources for these subtasks. Among the local computing resources, because test cases generation 212 and software simulation test 214 are completed by software tools, gateway layer 204 can allocate server 134a that can run the relevant software tools as computing resources for these two subtasks. However, hardware emulation test 216 needs to use a hardware verification tool, therefore, gateway layer 204 can allocate hardware verification tool 134b as a computing resource for this subtask.

Returning to FIG. 2A, scheduling layer 206 can be configured to invoke a plurality of computing resources according to a given process to execute a plurality of subtasks. Scheduling layer 206 can include a plurality of schedulers to provide different scheduling schemes. For example, scheduling layer 206 can include an HPC scheduler, a Kube scheduler, other third-party schedulers, and the like. Scheduling layer 206 can also be configured to communicate with computing resources 134 to obtain the current usage of computing resources 134, the execution status of running tasks, the execution results of completed tasks, and the like.

As discussed above, computing resources 134 can include a plurality of servers 134a and a plurality of hardware verification tools 134b. Each server 134a can be treated as a computing node. In some embodiments, server 134a can be further treated as a host connected with one or more hardware verification tools 134b, thereby including the one or more hardware verification tools 134b within the computing node. Each computing node is separately connected to each scheduler of scheduling layer 206. In some embodiments, the connection between the scheduler and hardware verification tool 134b needs to be implemented through server 134a as the host.

In some embodiments, computing resources 134 provide computing resources to resource manager 200 in a cloud-native manner. In this way, the increase or decrease of the underlying computing resources (e.g., servers or hardware verification tools) can not affect the provision of overall computing services.

While conventional technology can only start one EDA tool to complete one task (e.g., subtask in the present application) at a time, resource manager 200 of the embodiments of the present disclosure automates the execution of EDA tasks by reconstructing the process, so that the user does not have to keep an eye on the operation of EDA tools all the time and manually invoke the next EDA tool. It is appreciated that, conventionally, it is impossible to decompose one EDA task into a plurality of subtasks, reconstruct the process of one EDA task, and automatically allocate appropriate computing resources according to the characteristics of the subtasks.

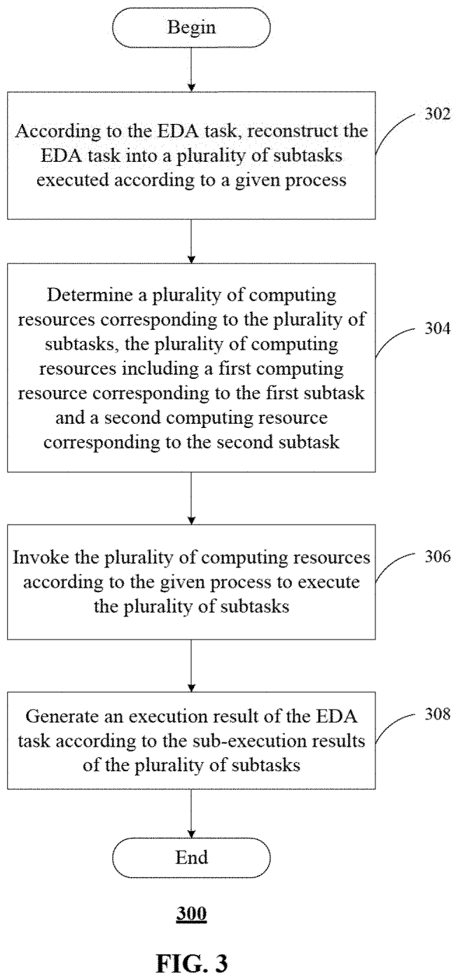

FIG. 3 is a flowchart of a method 300 for performing an EDA task according to embodiments of the present disclosure. Method 300 can be performed by, for example, computing device 132 as shown in FIG. 1C. And more specifically, method 300 can be performed by resource manager 200 as shown in FIG. 2A running on computing device 132. The EDA task can be a task related to a logic system design and to executed by one or more EDA tools. This disclosure takes an EDA task for verifying a logic system design as an example for illustration. The EDA task can be sent to resource manager 200 by a user via interface layer 202 as shown in FIG. 2A, and received by resource manager 200. Method 300 can include the following steps.

At step 302, according to the EDA task, resource manager 200 can reconstruct the EDA task (e.g., an EDA task for coverage testing, an EDA task for formal verification, or the like) into a plurality of subtasks (e.g., subtasks 212-218 of FIG. 2B, subtasks 222-228 of FIG. 2C) executed according to a given process (e.g., reconstructed process 210 of FIG. 2B, reconstructed process 220 of FIG. 2C). The plurality of subtasks can include a first subtask and a second subtask. It is appreciated that the sequential execution here does not refer to single-threaded execution, but also includes the possibility of parallel subtasks.

At step 304, resource manager 200 can determine a plurality of computing resources (e.g., local computing resource 134, cloud system 120 of FIG. 1C, or the like) corresponding to the plurality of subtasks. The plurality of computing resources can include a local computing resource (e.g., local computing resource 134 of FIG. 1C). The local computing resource can include at least one of a server (e.g., server 134a of FIG. 1C) or a hardware verification tool (e.g., hardware verification tool 134b of FIG. 1C). Hardware verification tools can include, for example, emulators or prototyping boards, and the like. In some embodiments, the plurality of computing resources can further include: a cloud computing resource (e.g., cloud system 120 of FIG. 1C). It is appreciated that, in some embodiments, the resources that resource manager 200 can invoke may not include the cloud computing resource.

In some embodiments, resource manager 200 can reconstruct the EDA task into a plurality of subtasks that are executed according to a given process based on a plurality of currently available computing resources. For example, when local computing resources 134 have a large number of idle servers, resource manager 200 can preferentially allocate local computing resources 134 for executing the plurality of subtasks. As another example, when the timeliness of the EDA task is very high and local computing resources cannot complete the computation on time, resource manager 200 can preferentially invoke cloud computing resource 120 to execute at least a part of the plurality of subtasks. Therefore, even for the same EDA task, resource manager 200 can generate different given processes and different plurality of subtasks when the plurality of computing resources currently available are different.

The plurality of computing resources can include a first computing resource corresponding to the first subtask and a second computing resource corresponding to the second subtask. In some embodiments, the first computing resource and the second computing resource are different types of computing resources. For example, the first computing resource is a server, and the second computing resource is a hardware verification tool. In some embodiments, the first computing resource and the second computing resource are the same type of computing resource. For example, the first computing resource is a first server, and the second computing resource is a second server.

In some embodiments, determining the plurality of computing resources corresponding to the plurality of subtasks further includes: determining whether inputs of the first subtask (e.g., task 222 or 224 of FIG. 2C) and the second subtask (e.g., task 226 of FIG. 2C) are source code secure; in response to determining the input of the first subtask is not source code secure, determining that the first computing resource corresponding to the first subtask is the local computing resource (e.g., local server 134a); and in response to determining the input of the second subtask is source code secure, determining that the second computing resource corresponding to the second subtask is the cloud computing resource (e.g., cloud system 120).

In some embodiments, determining the plurality of computing resources corresponding to the plurality of subtasks further includes: determining a plurality of EDA tools for respectively executing the plurality of subtasks; and determining a plurality of computing resources corresponding to the plurality of subtasks according to the plurality of EDA tools. For example, please refer to the description of FIG. 2B and FIG. 2C.

In some embodiments, the second subtask includes a plurality of parallel grandchild tasks. For example, when the second subtask is model-based solving 226 of FIG. 2C, the subtask 226 can include a plurality of parallel grandchild tasks.

At step 306, resource manager 200 can invoke the plurality of computing resources according to the given process to execute the plurality of subtasks. In some embodiments, invoking the plurality of computing resources according to the given process to execute the plurality of subtasks further includes: receiving sub-execution results of the first subtask and the second subtask; and combining the sub-execution results into a single execution result. For example, subtask 218 can combine the execution results of subtasks 214 and 216, and generate a single execution result.

In some embodiments, in the given process, the first subtask (e.g., subtask 214 or 216 of FIG. 2B) is a predecessor task of the second subtask (e.g., subtask 218 of FIG. 2B). And invoking the plurality of computing resources according to the given process to execute the plurality of subtasks further includes: invoking the first computing resource (e.g., server 134a or hardware verification tool 134b) to execute the first subtask; receiving a first execution result of the first subtask as the input of the second subtask; releasing the first computing resource; and invoking the second computing resource to execute the second subtask based on the first execution result.

At step 308, resource manager 200 can generate an execution result of the EDA task according to the sub-execution results of the plurality of subtasks.

Embodiments of the disclosure also provide a computing apparatus for performing an EDA task (e.g., computing apparatus 100 in FIG. 1A), including: a memory for storing a set of instructions; and at least one processor configured to execute the set of instructions to cause the computing system to perform method 300 as described above.

Embodiments of the disclosure also provide a computing system (e.g., computing system 201 in FIG. 2A) for performing an EDA task, including: the computing apparatus for performing an EDA task as described above; and local computing resources communicatively connected to the computing apparatus. The local computing resources include: at least one of a server or a hardware verification tool.

Embodiments of the present disclosure further provide a non-transitory computer-readable storage medium that stores a set of instructions of a computing apparatus. The set of instructions is used to cause the computing apparatus to perform the above-mentioned method 300.

As mentioned above, the method, apparatus, system, and storage medium for performing an EDA task provided by the present disclosure realize automatic execution of EDA tasks, global configuration of resources, collaboration among a plurality of EDA tasks (or tools) and secure cloud computing by reconstructing EDA tasks into a plurality of subtasks according to a given process sequence. It resolves a plurality of problems in the existing technologies.

Those skilled in the art can easily derive other embodiments of the present disclosure after considering and practicing the above disclosure. The present disclosure is aimed at covering any variations, use or adaptive changes of the present disclosure, and the variations, use or adaptive changes conform to the general principle of the present disclosure and include common knowledge or common technical means in the technical field not disclosed in the present disclosure. The specification and embodiments are merely regarded as exemplary, and the scope of the invention is defined by the accompanied claims.

It should be understood that the present disclosure is not limited to the accurate structure described above and illustrated in the drawings, and various modifications and changes can be made without departing from the scope thereof. The scope of the invention is only limited by the appended claims.

What is claimed is:

1. A method for performing an Electronic Design Automation (EDA) task, the method comprising:
reconstructing the EDA task into a plurality of subtasks that are executed according to a given process, the plurality of subtasks comprising a first subtask and a second subtask;
determining a plurality of computing resources corresponding to the plurality of subtasks, the plurality of computing resources comprising a first computing resource corresponding to the first subtask and a second computing resource corresponding to the second subtask; and
invoking the plurality of computing resources according to the given process to execute the plurality of subtasks.

2. The method of claim 1, further comprising:
generating an execution result of the EDA task according to sub-execution results of the plurality of subtasks.

3. The method of claim 1, wherein the plurality of computing resources comprise a local computing resource, the local computing resource comprising at least one of a server or a hardware verification tool.

4. The method of claim 3, wherein the plurality of computing resources further comprise a cloud computing resource.

5. The method of claim 4, wherein the EDA task is a verification task of a logic system design, and determining the plurality of computing resources corresponding to the plurality of subtasks further comprises:
determining whether inputs of the first subtask and the second subtask are source code secure;
in response to determining the input of the first subtask is not source code secure, determining that the first computing resource corresponding to the first subtask is the local computing resource; and
in response to determining the input of the second subtask is source code secure, determining that the second computing resource corresponding to the second subtask is the cloud computing resource.

6. The method of claim 1, wherein the first subtask is a predecessor task of the second subtask in the given process, and invoking the plurality of computing resources according to the given process to execute the plurality of subtasks further comprises:
invoking the first computing resource to execute the first subtask;
receiving an execution result of the first subtask as an input of the second subtask;
releasing the first computing resource; and
invoking the second computing resource to execute the second subtask based on the execution result of the first subtask.

7. The method of claim 1, wherein the second subtask comprises a plurality of parallel grandchild tasks.

8. The method of claim 1, wherein invoking the plurality of computing resources according to the given process to execute the plurality of subtasks further comprises:
receiving sub-execution results of the first subtask and the second subtask; and
combining the sub-execution results into a single execution result.

9. The method of claim 8, wherein the first computing resource is a server, and the second computing resource is a hardware verification tool.

10. The method of claim 1, wherein determining the plurality of computing resources corresponding to the plurality of subtasks further comprises:
determining a plurality of EDA tools for executing the plurality of subtasks, respectively; and
determining the plurality of computing resources corresponding to the plurality of subtasks according to the plurality of EDA tools.

11. A computing apparatus for performing an Electronic Design Automation (EDA) task, comprising:
a memory storing a set of instructions; and
at least one processor configured to execute the set of instructions to perform a method for performing the EDA task, the method comprising:
reconstructing the EDA task into a plurality of subtasks that are executed according to a given process, the plurality of subtasks comprising a first subtask and a second subtask;
determining a plurality of computing resources corresponding to the plurality of subtasks, the plurality of computing resources comprising a first computing resource corresponding to the first subtask and a second computing resource corresponding to the second subtask; and
invoking the plurality of computing resources according to the given process to execute the plurality of subtasks.

12. The computing apparatus of claim 11, wherein the at least one processor is further configured to execute the set of instructions to:
generate an execution result of the EDA task according to sub-execution results of the plurality of subtasks.

13. The computing apparatus of claim 11, wherein the plurality of computing resources comprise a local computing resource, the local computing resource comprising at least one of a server or a hardware verification tool.

14. The computing apparatus of claim 13, wherein the plurality of computing resources further comprise a cloud computing resource.

15. The computing apparatus of claim 14, wherein the EDA task is a verification task of a logic system design, and the at least one processor is further configured to execute the set of instructions to:
determine whether inputs of the first subtask and the second subtask are source code secure;
in response to determining the input of the first subtask is not source code secure, determine that the first computing resource corresponding to the first subtask is the local computing resource; and
in response to determining the input of the second subtask is source code secure, determine that the second computing resource corresponding to the second subtask is the cloud computing resource.

16. The computing apparatus of claim 11, wherein the first subtask is a predecessor task of the second subtask in the given process, and the at least one processor is further configured to execute the set of instructions to:
invoke the first computing resource to execute the first subtask;
receive an execution result of the first subtask as an input of the second subtask;
release the first computing resource; and
invoke the second computing resource to execute the second subtask based on the execution result of the first subtask.

17. The computing apparatus of claim 11, wherein the second subtask comprises a plurality of parallel grandchild tasks.

18. The computing apparatus of claim 11, wherein the at least one processor is further configured to execute the set of instructions to:
receive sub-execution results of the first subtask and the second subtask; and
combine the sub-execution results into a single execution result.

19. A computing system for performing an EDA task, comprising:
the computing apparatus of claim 11; and
local computing resources communicatively connected to the computing apparatus, the local computing resources comprising: at least one of a server or a hardware verification tool.

20. A non-transitory computer-readable storage medium storing a set of instructions that, when executed by a computing apparatus, causes the computing apparatus to perform a method for performing an Electronic Design Automation (EDA) task, the method comprising:
reconstructing the EDA task into a plurality of subtasks that are executed according to a given process, the plurality of subtasks comprising a first subtask and a second subtask;
determining a plurality of computing resources corresponding to the plurality of subtasks, the plurality of computing resources comprising a first computing resource corresponding to the first subtask and a second computing resource corresponding to the second subtask; and
invoking the plurality of computing resources according to the given process to execute the plurality of subtasks.
